(19) United States
(12) Patent Application Publication
(10) Pub. No.: US 2026/0211313 A1
(43) Pub. Date: Jul. 23, 2026

(54) LASER PROCESSING UNIT AND METHOD AND APPARATUS FOR MANAGING MASKS

(71) Applicant: ORC MANUFACTURING CO., LTD., Tokyo (JP)

(72) Inventors: Akira NAKAZAWA, Machida-shi (JP); Kohei YAMABE, Machida-shi (JP); Hiromu KOBAYASHI, Machida-shi (JP)

(73) Assignee: ORC MANUFACTURING CO., LTD., Tokyo (JP)

(21) Appl. No.: 19/086,633

(22) Filed: Mar. 21, 2025

(30) Foreign Application Priority Data
Jan. 21, 2025 (JP) 2025-008242

(51) Int. Cl. G03F 1/68; G03F 7/00

(52) U.S. Cl. CPC G03F 1/68; G03F 7/70025; G03F 7/70041; G03F 7/70358; G03F 7/70508; G03F 7/7085

(57) ABSTRACT

A laser-processing unit includes: a light source configured to oscillate a laser beam; an illumination optical unit configured to form a laser beam for processing from an oscillated laser beam, the laser beam for processing being used to irradiate a mask mounted on a mask stage; and a measuring processor configured to record a value corresponding to the cumulative amount of irradiation energy from the laser beam for processing, in accordance to an irradiation position.

### BACKGROUND OF THE INVENTION

### 1. Field of the Invention

The present invention relates to a laser-processing unit that forms a pattern on a workpiece such as a substrate by laser ablation using a laser beam with high energy density, and it especially relates to the management of a photomask (hereinafter, called a “mask”).

### 2. Description of the Related Art

A laser ablation process can accurately form a pattern on a workpiece such as a printed wiring board. In a laser-processing unit or machine, a laser beam is scanned over a mask and part of the laser beam that passes through a mask pattern is projected onto a substrate. A laser beam with high energy density melts or evaporates the surface of the substrate to form a processed pattern such as a via hole or a trench for wiring in the substrate.

Suwa et al. (US2021/0046584Al) discloses a laser-processing unit with a line-beam forming optical unit, which forms a line-shaped laser beam. A scanning mechanism moves the line-beam optical unit to scan the line-shaped laser beam over a mask.

Generally, a mask has a mask pattern and metallic film is formed around the mask pattern. The metallic film deteriorates and may be damaged by a laser beam with extremely high energy density (fluence) irradiating the mask.

To form a pattern such as a via hole on a variety of substrates, a plurality of masks is prepared in advance and one mask is selected. Also, there is a mask with a plurality of mask patterns. The number of times scanned and the dimensions of the scanning area vary with a mounted substrate.

Consequently, the amount of irradiance from a laser beam is different for each mask and varies with respect to the irradiation area in each mask. Therefore, it is difficult to predict the timing of when a mask needs to be exchanged before the mask deteriorates and becomes damaged.

### SUMMARY OF THE INVENTION

A laser-processing unit according to the present invention includes: a light source configured to oscillate a laser beam; an illumination optical unit configured to form a laser beam from the oscillating laser beam to be used in materials processing, the laser beam for processing being used to irradiate a mask mounted on a mask stage; and a measuring processor configured to measure a cumulative amount of irradiation energy from the laser beam for processing, in accordance to an irradiation position.

An apparatus for managing a mask according to another aspect of the present invention includes: a measuring processor configured to measure a cumulative amount of irradiation energy delivered by a laser beam for processing, in accordance to an irradiation position; and a managing processor configured to manage the usage status of the mask based on the value corresponding to the cumulative amount of irradiation energy.

A method for managing a mask according to another aspect of the present invention includes: a) measuring a cumulative amount of irradiation energy delivered by the laser beam for processing, in accordance to an irradiation position, the laser beam for processing being used to irradiate a mask mounted on a mask stage provided in a laser-processing unit; and b) managing the usage status of the mask based on a value corresponding to the cumulative amount of irradiation energy.

### BRIEF DESCRIPTION OF THE DRAWINGS

The present invention will be better understood from the description of the preferred embodiment of the invention set forth below together with the accompanying drawings, in which:

FIG. 1 is a schematic view showing a laser-processing unit according to the present embodiment;

FIG. 2 is a block diagram of the laser-processing unit;

FIG. 3 illustrates a mask mounted on a mask stage 40;

FIG. 4 illustrates the number of pulses in each element of the grid defined on the mask;

FIG. 5 is a flowchart of a process for measuring and recording cumulative pulse numbers in a laser ablation process;

FIG. 6 illustrates a screen that displays a series of cumulative pulse numbers in each mask;

FIG. 7 illustrates a monitoring screen different from the monitoring screen shown in FIG. 6; and

FIG. 8 illustrates a recipe to the mask that is different from the recipe shown in FIG. 3.

### DESCRIPTION OF THE PREFERRED EMBODIMENTS

Hereinafter, the preferred embodiment of the present invention is described with references to the attached drawings.

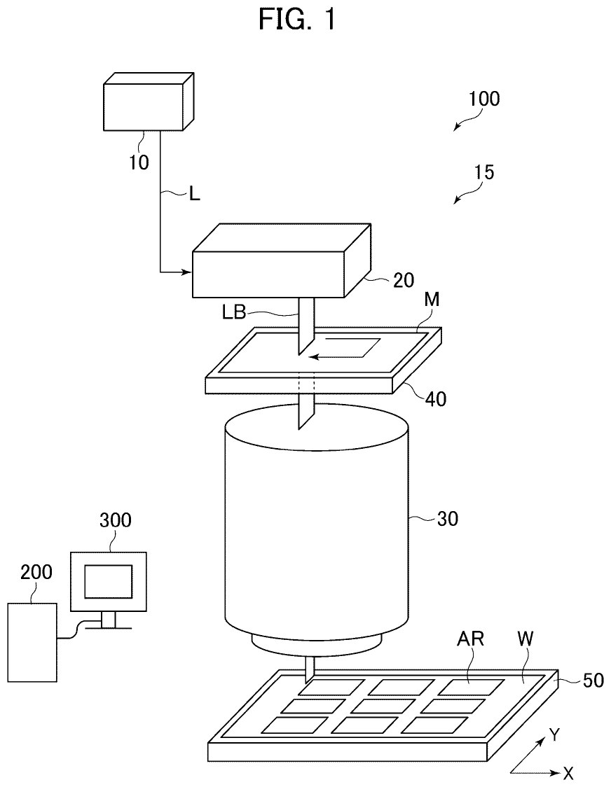

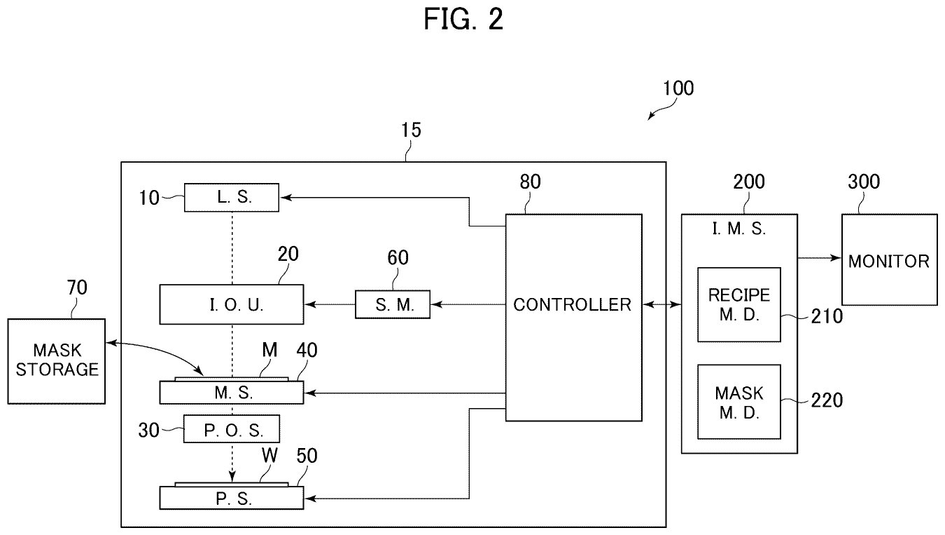

FIG. 1 is a schematic view showing a laser-processing unit according to the present embodiment. FIG. 2 is a block diagram of the laser-processing unit.

A laser-processing unit 100 forms a pattern on a substrate W by laser ablation and is equipped with a light source 10, a body 15, and an information management system 200. The laser 10 oscillates a laser beam with high energy density. Herein, the laser 10, which is an excimer laser that emits a KrF excimer laser beam in a pulse with a wavelength of 248 nm, is located at a position separate from but adjacent to the body 15. A laser beam oscillated from the laser 10 is directed to the body 15 via a laser delivery system (not shown).

The body 15 is equipped with an illumination optical unit 20, a projection optical system 30, a mask stage 40 a processing stage 50 and a scanning mechanism 60 (not shown in FIG. 1), which are supported by a supporting structure (not shown) provided in the body 12. A mask M and a substrate W are mounted on the mask stage 40 and the processing stage 50, respectively.

The illumination optical unit 20 is equipped with a line-beam forming optical system (not shown) including a cylindrical lens, an angle-switching mirror, etc. The line-beam forming optical system forms a line-shaped laser beam LB from the laser beam L that enters the illumination optical unit 20 along the main-scanning direction. The line-shaped laser beam LB is directed onto the mask M via a mirror (not shown).

The illumination optical unit 20, which is supported by the scanning mechanism 60, reciprocates along the main-scanning direction as the scanning mechanism 60 moves along the scanning direction. Accordingly, the line-shaped laser beam LB moves relative to the mask M and the substrate W. Consequently, the mask M and the substrate W are scanned. Herein, the X-axis and Y-axis are defined along the main-scanning direction and the sub-scanning direction, respectively. Also, the Z-axis is defined along the vertical direction.

The mask stage 40 supports the mask M and may move the mask M along the main-scanning and sub-scanning directions (the X-axis and Y-axis directions) and rotate the mask M around the vertical direction (Z-axis direction) to maneuver the mask M into a given position. The projection optical system 30, which has focus points on the surfaces of the mask M and the substrate W, projects a beam through the mask M onto the substrate W as a pattern beam. Herein, the projection optical system 30 is a reduced-lens optical system, which has a projection magnification less than 1 (e.g., 0.25).

The processing stage 50 functions as a workpiece chuck to secure the substrate W to the processing stage 50 by vacuum suction. Also, the processing stage 50 moves the substrate W along the main-scanning and sub-scanning directions (the X-axis and the Y-axis directions) and rotates the substrate W around the vertical direction (Z-axis direction) to position the substrate W relative to the mask M. Furthermore, the processing stage 50 may move along main-scanning direction (the X-axis direction) step by step to carry out an ablation processing for the entire substrate W.

The mask M is composed of material(s) that allows the line-shaped laser beam LB to penetrate it (e.g., quartz glass). Then, a shielding-film (herein, a metallic film) that shields the line-shaped laser beam LB and corresponds to the form of the mask pattern is formed on the surface of the mask M.

The laser-processing unit 100 is equipped with mask storage 70. The mask storage 70 may store a plurality of masks that have different mask patterns, respectively. A mask conveyer (not shown) picks out a mask that is selected by an operator from the mask storage 70 and mounts the selected mask on the mask stage 40.

In the substrate W, a copper wiring layer is formed on an epoxy resin and an insulation layer is further formed on the copper wiring layer. As described above, the light source 10 irradiates the substrate W with the excimer laser beam with high energy density, which ablates, i.e., removes material from the substrate W, so that a pattern corresponding to a mask pattern (hereinafter, “processed pattern”) is formed on the substrate W.

As for the processed pattern, an interstitial via hole, blind via hole, wiring groove (trench), etc., can be formed on the substrate W. After the laser ablation process for the substrate W is finished, the substrate W is filled with a conductor such as copper.

A controller 80 controls the light source 10 and the scanning mechanism 60 to move the line-shaped laser beam LB along the main-scanning direction (the X-axis direction) in accordance with an input operation for a laser ablation process.

An information management system 200 is equipped with a recipe management department 210 and a mask management department 220. The recipe management department 210 manages recipe information, which includes an output of the laser beam L, the scanning-speed of the line-shaped laser beam LB, and mask-pattern information. The mask management department 220 manages usage status of masks. The information management system 200 is herein a computer with a human-machine interface (HMI). An operator may manipulate system controls while watching recipe information displayed on a display 300 such as a monitor.

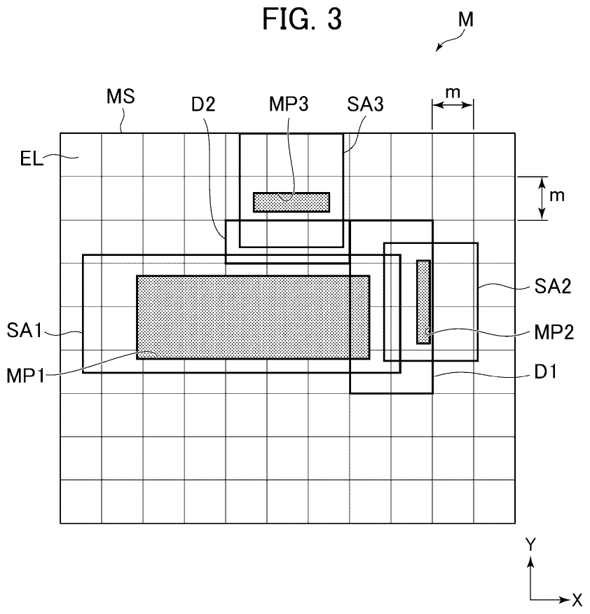

The mask management department 220 measures irradiation energy of the line-shaped laser beam LB that irradiates the mask M, based on the usage status of each mask selected. At the same time, the mask management department 220 records and manages a cumulative amount of irradiation energy of the line-shaped laser beam LB. Furthermore, the mask management department 220 displays a cumulative amount of irradiation energy of the line-shaped laser beam LB and provides alerts for a mask lifetime or mask exchange timing using the display 300. Hereinafter, the management of mask usage will be explained with reference to FIGS. 3 to 8.

FIG. 3 illustrates a mask M mounted on the mask stage 40.

As shown in FIG. 3, three mask patterns MP1, MP2 and MP3, which are apart from one another, are formed on the mask M. Herein, each mask pattern is a rectangular pattern, however, another pattern may be formed. For example, a group of via-hole patterns that are arrayed in a rectangular area, or singular or plural cavity pattern(s) may be formed on the mask M.

The width of the line-shaped laser beam LB is longer than the widths of the mask patterns MP1, MP2 and MP3 in the sub-scanning-direction (the Y-axis direction). When forming the mask pattern MP1, a scanning area SA1 that surrounds the mask pattern MP1 is defined. Similarly, a scanning area SA2 that surrounds the mask pattern MP2 and a scanning area SA3 that surrounds the mask pattern MP3 are formed on the mask M. The line-shaped laser beam LB is scanned over the scanning areas SA1, SA2 and SA3 during a laser ablation process to form a processed pattern.

When using the mask M to form a processed pattern on each patterning area AR on the substrate W, the scanning areas SA1, SA2 and SA3 are utilized in a laser ablation process. When using the mask M to conduct a laser ablation process for a next substrate W, the scanning area SA1, SA2 and SA3 are also utilized. The line-shaped laser beam LB is scanned over the mask M repeatedly.

The laser beam oscillated from the light source 10 is a pulse laser beam with the width of one pulse and a given energy density (fluence). Therefore, a generally uniform amount of energy is supplied to an irradiated area of the mask M every time a pulse laser beam L is oscillated as the line-shaped laser beam LB moves over the mask M at a given scanning speed.

The metallic film that constitutes a light-shielding segment of the mask M has a strong resistance to the laser beam L. Also, the energy density of a pattern beam that passes through the mask M is relatively low since the projection optical system 30 is a reduced-projection optical system. However, the metallic film gradually wears out and deteriorates as the line-shaped laser beam LB repeatedly irradiates the mask M. Damage the size of a pinhole occasionally occurs during long-term usage.

Wear or deterioration of the metallic film is associated with cumulative energy of the line-shaped laser beam LB. The laser-processing unit 100 measures the cumulative amount of a value corresponding to an irradiation energy and monitors the usage status of the mask M. Then, the laser-processing unit 100 displays information associated with the usage status, a predicted lifetime of the mask M, and a timepoint for exchanging the mask M.

As described above, the line-shaped laser beam LB is scanned over the scanning areas SA1, SA2 and SA3, which are apart from one another on the mask M and do not constitute the entire mask M. The cumulative amount of irradiation energy on the surface of the mask M is not uniform and varies with respect to an irradiated position. Accordingly, a cumulative amount of irradiation energy is measured in accordance to the position of the mask M.

As shown in FIG. 3, the surface of the mask M is divided into sections to form a grid or mesh MS. Each section of the grid MS (hereinafter, called a “element”) has the same size. The size of each element EL depends upon the size of the mask M, the energy density necessary for a laser ablation process, the scanning speed of the line-shaped laser beam LB during a laser ablation process, etc. The dimensions of the element EL (m×m) are herein set to 1 (mm)×1 (mm), and eleven elements EL are aligned in the main-scanning direction (the X-axis direction) and nine elements EL are aligned in the sub-scanning direction (the Y-axis direction), namely, ninety-nine elements EL are arranged in a matrix.

On the mask M, the scanning areas SA1 and SA2 overlap with one another and the scanning areas SA1 and SA3 are next to one another. The region D1 that is defined along grid lines is constructed of a group of eight elements EL in which each element EL has part of the scanning area SA1 and SA2. The region D2 is constructed of a group of three elements EL in which each element EL includes the neighboring portions of scanning area SA1 and SA3

The mask M receives irradiation energy when the laser beam L is oscillated in a pulse. Therefore, the number of pulses can be regarded as a value corresponding to the cumulative amount of irradiation energy supplied by the line-shaped laser beam LB. Since the energy distribution of the line-shaped laser beam LB is approximately constant in the sub-scanning direction (the Y-axis direction), the number of pulses that are oscillated while the line-shaped laser beam LB passes through the width of an element EL (herein, 1 mm) in the main-scanning direction (the X-axis direction) can be regarded as corresponding to the above value. Hereinafter, the number of pulses can be called a “value corresponding to a cumulative irradiation energy”, if necessary.

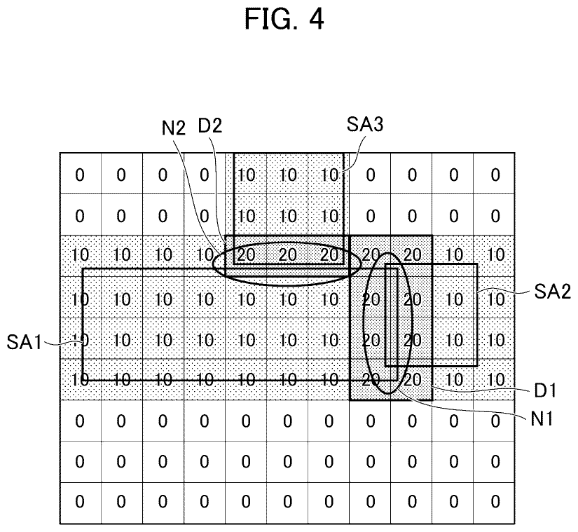

FIG. 4 illustrates the number of pulses in each element EL of the grid MS defined on the mask M. Herein, the mask M is irradiated by ten pulses from the line-shaped laser beam LB while it passes through one element EL.

As for elements EL that are not included in the scanning areas SA1, SA2 and SA3 nor cross into the boundaries of the scanning areas SA1, SA2 and SA3, they are not irradiated by the line-shaped laser beam LB. The number of pulses is counted as “zero”. On the other hand, as for elements EL that are included in the scanning areas SA1, SA2 and SA3 or cross into the boundary of the scanning areas SA1, SA2 and SA3, the number of pulses is set to ten or twenty.

The region D1 includes both an overlapping area and a nonoverlapping area regarding irradiation by the line-shaped laser beam LB. The line-shaped laser beam LB is not scanned over the entire region D1. However, considering that the overlapping area tends to deteriorate, the number of pulses in each element EL of the region D1 is set to the combined number of pulses in the scanning areas SA1 and SA2, i.e., 20 pulses.

As for the three elements EL in the region D2, parts of the scanning areas SA1 and SA3 are included and close to one another. On the other hand, the scanning areas SA1 and SA3 do not overlap with one another in the region D2. However, considering that two times the amount of scanning by the line-shaped laser beam LB is carried out in the three elements EL, the number of pulses in the three elements EL in region D1 is set to twenty, by adding the number of pulses in the scanning area SA1 to the number of pulses in the scanning area SA3.

After the number of pulses for each element EL is set, the number of pulses is added to the total number of past pulses that were previously counted and recorded, for each element EL. Thus, the number of pulses, i.e., the value corresponding to irradiation energy can be accumulated. Since irradiation energy from the line-shaped laser beam LB can be measured in real time, an operator can monitor and figure out usage status or timing for exchanging the mask M.

As for the elements EL in the regions D1 and D2, the number of pulses that are added to the previous cumulative value is set to a value (=twenty) larger than the number of pulses (=ten) for the other regions on the mask M. Thus, damage sustained in a position where irradiation energy is concentrated can be monitored correctly. A value to be added may be determined in accordance to the degree of overlap or proximity.

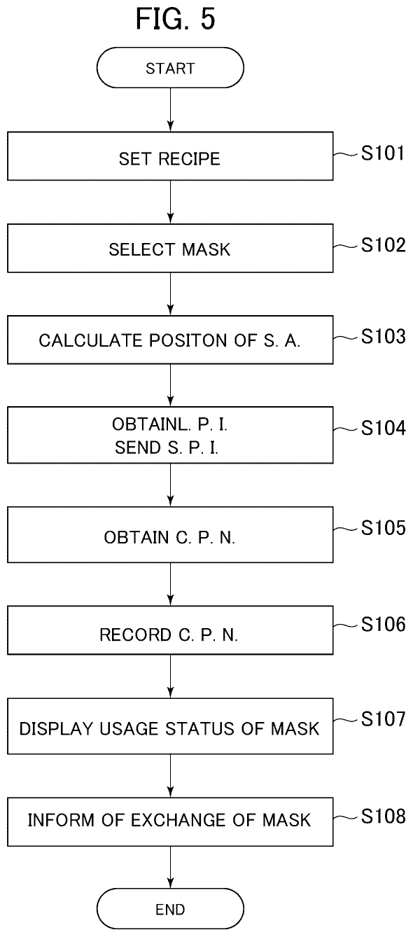

FIG. 5 is a flowchart of a measuring and recording process of cumulative pulse numbers in a laser ablation process. The mask management department 220 herein carries out the measurement of the number of pulses, etc.

The recipe management department 210 stores and manages a plurality of recipe data. Also, a mask-ID is linked to each mask stored in the mask storage 70 and managed. When an operator manipulates a manipulator provided in the information management system 200 to input parameters associated with a recipe and select a mask, the selected mask (herein, the mask M) is conveyed from the mask storage 70 (Step 101 and Step 102)

The mask management department 220 acquires information associated with scanning areas (herein, SA1, SA2 and SA3) of the selected mask M, based on mask ID and determined recipe data (Step 103). The positions of the scanning areas SA1, SA2 and SA3 are represented by the x-y coordinates defined on the mask M. Note that the x-y coordinates are calibrated from the X-Y coordinates in accordance to the reduced magnification of the projection optical system 30.

To carry out a laser ablation process, recipe data and scanning-position information are sent to the controller 80. On the other hand, the controller 80 sends laser pulse information of the light source 10 to the information management system 200 (Step 104). The laser pulse information is a predetermined pulse number in accordance to the size of element EL in each processing area AR (See FIG. 1). Herein, the number of pulses is set to ten or twenty.

The mask management department 220 sets the number of pulses in each element EL of the grid MS based on the received laser pulse information and the scanning position information. Then, the number of pulses is added to the previous total pulse numbers that are counted in a laser ablation process using the mask M. A newly obtained cumulative pulse number is recorded in a database provided in the information management system 200 (Step 105 and Step 106). When a processed area AR is changed to a next processing area AR, the number of pulses is counted and the cumulative number is recorded in the database. Note that a cumulative pulse number may be recorded in a process-management database (not shown) that records production status.

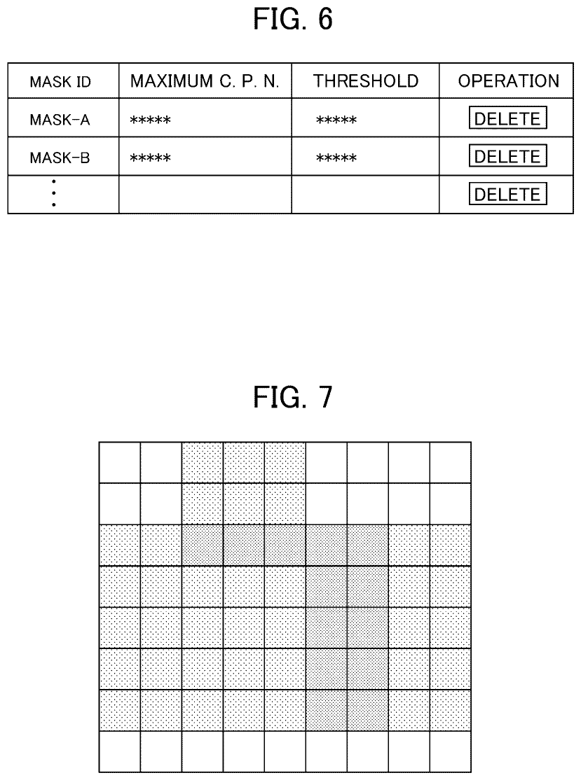

FIG. 6 illustrates a screen that displays a series of cumulative pulse numbers in each mask. The display 300 displays the screen shown in FIG. 6 by an operator's input operation.

The mask management department 220 monitors usage status of a mask and can display lifetime and exchange timing information of a mask. Herein, an element that has a maximum cumulative pulse number is sampled from all the elements EL defined on the selected mask M. The sampled value and a predetermined threshold are displayed on the screen side by side.

When the maximum cumulative pulse number is greater than the threshold, a warning indicator suggests an exchange of the mask M since the lifetime of the mask M is approaching its end. For example, a warning mark is displayed on the screen to inform an operator of a warning status (Step 107 and Step 108).

FIG. 7 illustrates a monitoring screen different from the monitoring screen shown in FIG. 6.

In FIG. 7, the cumulative pulse numbers are displayed as an image, for each element EL of the mask M. Concretely, a coloration or graduation varies with the cumulative pulse numbers. This represents the distribution of a value corresponding to irradiation energy. FIG. 7 illustrates a distribution of the cumulative pulse numbers shown in FIG. 4.

In this way, the laser-processing unit 100 equipped with the information management system 200 and the mask management department 220 utilizes the information management system 200 to manage usage status of each mask stored in the mask storage 70. A mask that is selected when carrying out a laser ablation process is divided in a grid figuratively. At this time, the number of pulses corresponding to an amount of irradiation energy of the line-shaped laser-beam LB is set in each element EL of the grid MS. Then, the determined pulse numbers are added to the previous cumulative total pulse numbers for each element EL and the newly cumulative pulse numbers are recorded.

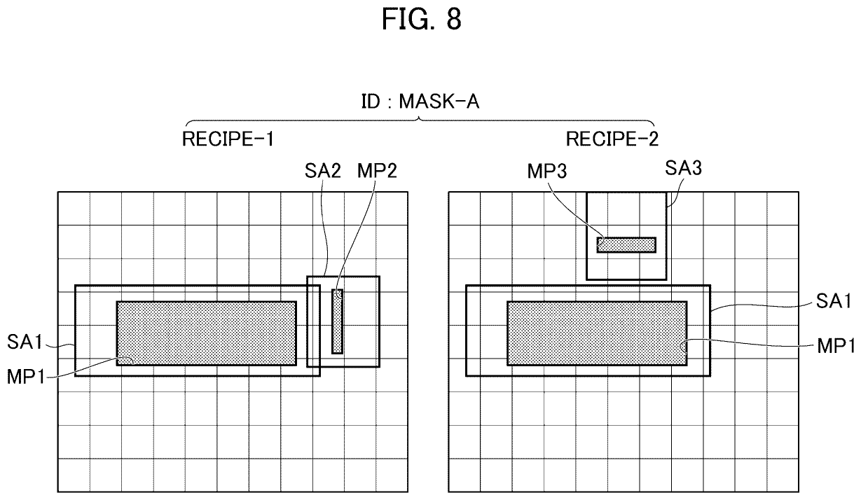

FIG. 8 illustrates a recipe to the mask M that is different from the recipe shown in FIG. 3.

Herein, a processed pattern WA is not the same in each processing area AR and the content of a recipe is exchanged when carrying out a laser ablation process. As shown in FIG. 8, the scanning areas of recipe-1 and a recipe-2 are determined, respectively. The number of pulses is set in each element EL based on the scanning positional information, the number of scans, information of the pulse laser beam L, etc. Then, the cumulative number of pulses in each element EL are counted and recorded.

A light amount may be measured cumulatively in each irradiation position, instead of the number of pulses. In this case, a continuous laser beam can oscillate from the light source 10. The size of an element of the grid MS or how to separate the mask M is arbitrary.

The recipe management department 210 or the mask management department 220 that functions as a measuring processor are herein constructed of a signal processor (circuitry) i.e., hardware such as an ASIC, respectively. However, these may be constructed of firmware such as an FPGA or software such as a CPU. In this case, the processing is carried out by a computer readable program code that is stored in a memory. Also, the management of mask usage may be carried out by a server. The server manages communications with the body 15 in the laser-processing unit 100 to manage mask usage.

Finally, it will be understood by those skilled in the arts that the foregoing description is of preferred embodiments of the device, and that various changes and modifications may be made to the present invention without departing from the spirit and scope thereof.

The present disclosure relates to subject matter contained in Japanese Patent Application No. 2025-008242 (filed on January 21, 2025), which is expressly incorporated herein by reference, in its entirety.

1. A laser-processing unit, comprising:
a light source configured to oscillate a laser beam;
an illumination optical unit configured to form a laser beam for processing from an oscillated laser beam, the laser beam for processing irradiating a mask mounted on a mask stage; and
a measuring processor configured to record a value corresponding to the cumulative irradiation energy from the laser beam for processing, in accordance to an irradiation position.

2. The laser-processing unit according to claim 1, further comprising a scanner configured to scan said mask with the laser beam for processing, said measuring processor increasing the value corresponding to irradiation energy for an overlap region and neighboring region among a plurality of scanning areas.

3. The laser-processing unit according to claim 1, wherein said measuring processor divides the surface of said mask into a grid, said measuring processor recording the value corresponding to cumulative irradiation energy for each element of the grid.

4. The laser-processing unit according to claim 1, wherein said light source oscillates a pulse laser beam, said measuring processor recording the value corresponding to irradiation energy based on the number of pulses.

5. The laser-processing unit according to claim 1, wherein said illumination optical unit forms a line-shaped laser beam for processing from the oscillated laser beam.

6. The laser-processing unit according to claim 1, further comprising a display processor configured to display on a screen a numerical value and/or an image of a cumulative value corresponding to cumulative irradiation energy.

7. The laser-processing unit according to claim 1, further comprising a monitoring processor configured to monitor the value corresponding to irradiation energy, said monitoring processor sampling a maximum value among a series of values corresponding to irradiation energy corresponding to predetermined irradiation positions.

8. The laser-processing unit according to claim 7, further comprising an information processor configured to announce information associated with a lifetime of said mask when the maximum value exceeds a threshold.

9. An apparatus for managing masks, comprising:
a measuring processor configured to record a value corresponding to cumulative irradiation energy from a laser beam for processing, in accordance to an irradiation position; and
a managing processor configured to manage usage status of said mask based on the value corresponding to irradiation energy.

10. A method for managing masks, comprising:
a) recording a value corresponding to cumulative irradiation energy from the laser beam for processing, in accordance to an irradiation position, the laser beam for processing irradiating a mask mounted on a mask stage provided in a laser-processing unit; and
b) managing usage status of said mask based on the value corresponding to cumulative irradiation energy.

11. The method according to claim 10, wherein the laser beam is a pulse laser beam, the recorded value being measured by determining the value corresponding to irradiation energy based on the number of pulses.

12. The method according to claim 10, wherein the surface of said mask is divided into a grid, the recorded value being measured by the value corresponding to cumulative irradiation energy, for each element of the grid.

13. The method according to claim 10, wherein the managing is accomplished by sampling a maximum value among a series of values corresponding to irradiation energy corresponding to predetermined irradiation positions.
